(19) United States
(12) Patent Application Publication
(10) Pub. No.: US 2013/0075835 A1
(43) Pub. Date: Mar. 28, 2013

(54) MICRO-ELECTRO-MECHANICAL MICROPHONE AND MICRO-ELECTRO-MECHANICAL MICROPHONE CHIP INTEGRATED WITH FILTER

(71) Applicants: Hung-Jen CHEN, Taichung (TW); Kuan-Hsun CHIU, Taichung (TW); Ju-Mei LU, Taichung (TW); Ming-Li HSU, Taichung (TW); Chun-Chieh WANG, Taichung (TW)

(72) Inventors: Hung-Jen CHEN, Taichung (TW); Kuan-Hsun CHIU, Taichung (TW); Ju-Mei LU, Taichung (TW); Ming-Li HSU, Taichung (TW); Chun-Chieh WANG, Taichung (TW)

(73) Assignee: MERRY ELECTRONICS (SHENZHEN) CO., LTD., Shen Zhen (CN)

(21) Appl. No.: 13/241,956

(22) Filed: Sep. 23, 2011

(51) Int. Cl. H01L 29/84

(52) U.S. Cl. 257/416; 257/E29.324

(57) ABSTRACT

A microelectromechanical microphone comprises a shell body, a microelectromechanical microphone chip and an integrated circuit. The shell body having a cavity and an opening, sound from outside enters into the cavity from the opening. The microelectromechanical microphone chip and the integrated circuit are disposed on a circuit layout inside the cavity. A filter is integrated with the microelectromechanical microphone chip at an appropriate location. Sound entered from the opening into the cavity is received by the microelectromechanical microphone chip, then the sound or audio signals are converted to electrical signals through the filter and the integrated circuit, to be transmitted to external electronic devices.

### BACKGROUND OF THE INVENTION

1. Field of Invention

The present invention relates to a microelectromechanical microphone and more particularly to a microelectromechanical microphone with a filter integrated directly into a microelectromechanical microphone chip.

2. Related Art

Referring to FIG. 1, it shows a layout for internal elements of a conventional microelectromechanical microphone. The microelectromechanical microphone includes a base plate 10 and a cover 11 disposed on top of the base plate 10 to form a cavity 12. An opening 111 is disposed on top of the cover 11 for connecting the cavity 12 with external environment, so that sound from outside can enter inside the cavity 12. Furthermore, the base plate 10 has an electrical circuit layout for electrically connecting with a microphone chip 13, an integrated circuit 14 and a capacitor 15. The microphone chip 13 receives sound entered inside the cavity 12 from the opening 111. The sound is then processed by the integrated circuit 14 and the capacitor 15 to be converted to electrical signals for transmitting to external electronic devices such as cell phones or laptops, etc.

This type of microelectromechanical microphone is commonly used in electronic devices such as cell phones or laptops, etc., which have a large number of antennas. Therefore, conventional microelectromechanical microphones are often interfered by radio frequency from the antennas and thus will affect the quality of communication. The capacitor 15 is used for filtering out high frequency signals of 900 MHz and 1800 MHz, in order to protect the microelectromechanical microphones from high radio frequency.

However, space needed for the disposition of the capacitor 15 makes it impossible to reduce the size of conventional microelectromechanical microphones. Thus, it is becoming unpractical for the demand of slim and compact electronic devices.

### SUMMARY OF THE INVENTION

In order to tackle the problem mentioned above, the present invention of a microelectromechanical microphone is designed with a filter integrated directly into a microelectromechanical microphone chip.

To achieve the objective, a microelectromechanical microphone of the present invention comprises a shell body, a microelectromechanical microphone chip and an integrated circuit. The shell body has a cavity and an opening, such that sound from outside enters into the cavity from the opening. The microelectromechanical microphone chip and the integrated circuit are disposed on a circuit layout inside the cavity. A filter is integrated with the microelectromechanical microphone chip at an appropriate location. Sound entered from the opening into the cavity is received by the microelectromechanical microphone chip, then the sound or audio signals are converted to electrical signals through the filter and the integrated circuit, to be transmitted to external electronic devices.

Furthermore, in the microelectromechanical microphone of the present invention, a microelectromechanical microphone chip comprises a base plate, a vibration membrane, a back plate and a filter. Wherein, the base plate has a cavity and the vibration membrane is disposed on top of the cavity. The back plate covers the vibration membrane and maintains a distance from the vibration membrane, and the back plate has a plurality of sound holes. The filter is disposed on the base plate and adjacent to the vibration membrane and the back plate.

According to the present invention, the filter is directly integrated into the microelectromechanical microphone chip, so that the manufacturing process for assembling a filter on a base plate is not necessary anymore. The present invention makes it possible that, without increasing the size of the microelectromechanical microphone chip, the size of the base plate, and even the size of the microelectromechanical microphone itself can be reduced. Furthermore, the processes of die bonding and wire bonding are not needed anymore because the process for disposing the filter on the base plate is bypassed, in order to save the cost of packaging process.

The present invention will become more fully understood by reference to the following detailed description thereof when read in conjunction with the attached drawings.

### BRIEF DESCRIPTION OF THE DRAWINGS

FIG. 1 is a layout of internal elements of a conventional microelectromechanical microphone;

FIG. 2 is a layout of internal elements of a microelectromechanical microphone according to the present invention;

FIG. 3 is an illustration of the manufacturing process of a microelectromechanical microphone chip with a first insulating layer and a second insulating layer disposing on a base plate according to the present invention;

FIG. 4 is an illustration of the manufacturing process of a vibration membrane and a first electrode of the present invention of a microelectromechanical microphone chip according to the present invention;

FIG. 5 is an illustration of the manufacturing process of a sacrificial layer being deposited on a microelectromechanical microphone chip according to the present invention;

FIG. 6 is an illustration of the manufacturing process of a third insulating layer and a capacitor dielectric layer of a microelectromechanical microphone chip according to the present invention;

FIG. 7 is an illustration of the manufacturing process of a back plate and a second electrode of a microelectromechanical microphone chip according to the present invention;

FIG. 8 is an illustration of the manufacturing process of etching of a base plate of a microelectromechanical microphone chip according to the present invention;

FIG. 9 is an illustration of the manufacturing process of removing a sacrificial layer of a microelectromechanical microphone chip according to the present invention;

FIG. 10 is an illustration of the structure of a microelectromechanical microphone chip formed by another manufacturing process according to the present invention;

FIG. 11 is an illustration of the structure of a microelectromechanical microphone chip formed by yet another manufacturing process according to the present invention;

FIG. 12A is a top perspective view of FIG. 2 of a microelectromechanical microphone chip according to the present invention; and

FIG. 12B is a top perspective view of another embodiment of a microelectromechanical microphone chip according to the present invention.

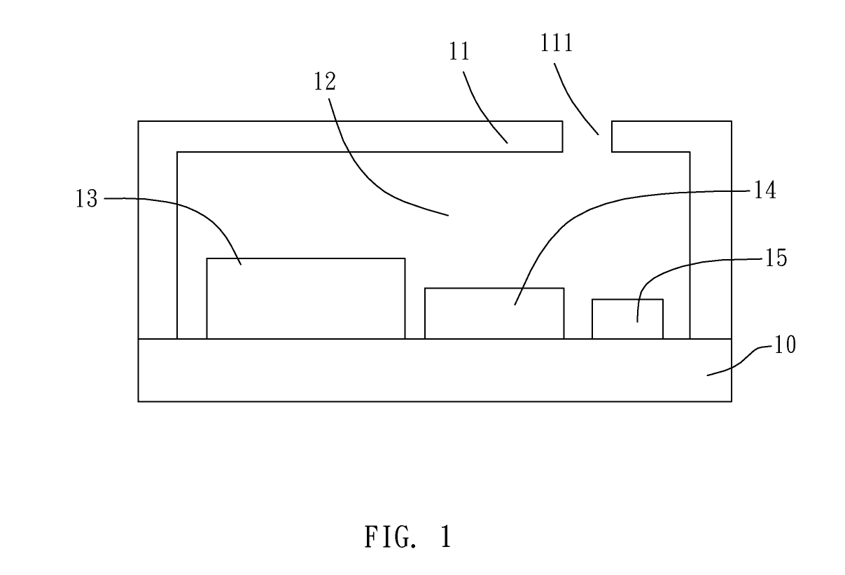

### DETAILED DESCRIPTION OF THE INVENTION

Hereinafter, a microelectromechanical microphone chip of the present invention will be described with reference to accompanying drawings.

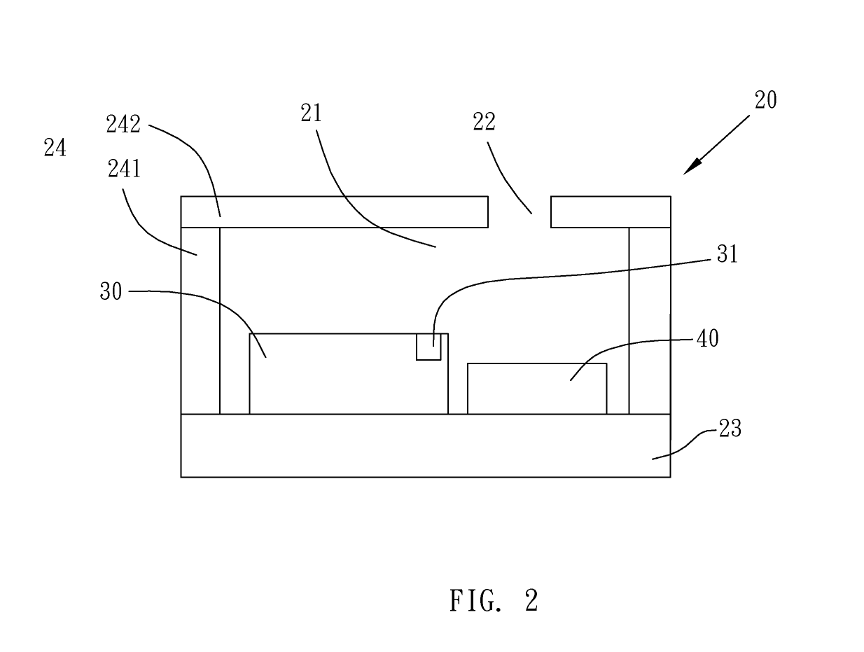

Referring to FIG. 2, it shows a layout of internal elements of a microelectromechanical microphone of the present invention. The microelectromechanical microphone comprises a shell body 20, a microelectromechanical microphone chip 30 and an integrated circuit 40. Wherein, the shell body 20 has a cavity 21 and an opening 22, and the opening 22 connects the cavity 21 with external environment. The microelectromechanical microphone chip 30 is disposed on a circuit layout inside the cavity 21. In addition, a filter 31 is disposed in the microelectromechanical microphone chip 30 at an appropriate location. The integrated circuit 40 is disposed on the circuit layout and is electrically connected with the microelectromechanical microphone chip 30. Moreover, the microelectromechanical microphone chip 30 receives sound entered inside the cavity 21 from the opening 22. The sound is then processed by the filter 31 and the integrated circuit 40 to be converted to electrical signals for transmitting to external electronic devices such as cell phones or laptops, etc.

The shell body 20 in this embodiment is composed of a base plate 23 and a cover 24. The cover 24 is composed of a middle plate 241 and an upper plate 242 which are stacked together. The opening 22 is disposed on the upper plate 242 at an appropriate position. However, in the present invention, the cover 24 can also be a metal cover formed in one piece with the opening 22 disposing at an appropriate position and covers the base plate 23 directly. Additionally, the opening 22 is not limited to be disposed on the cover 24 only, it can be disposed on the base plate 23 at an appropriate position. It will not be illustrated by figures as other variations and modifications are readily attainable by a person of average skill with a thorough understanding of the technical details of the present invention.

The base plate 23 in this embodiment is a printed circuit board with circuit layout disposed on it for the microelectromechanical microphone chip 30 and the integrated circuit 40 to connect electrically to the base plate 23. The filter 31 embedded on the microelectromechanical microphone chip 30 is a capacitor.

The disclosure below is the manufacturing process of the microelectromechanical microphone chip 30 according to the present invention. It describes how to integrate the filter 31 on the microelectromechanical microphone chip 30. Wherein, different layer structures in the manufacturing process are corresponding depositions. For the sake of concision, the layer structures under the base plate are omitted in the figures.

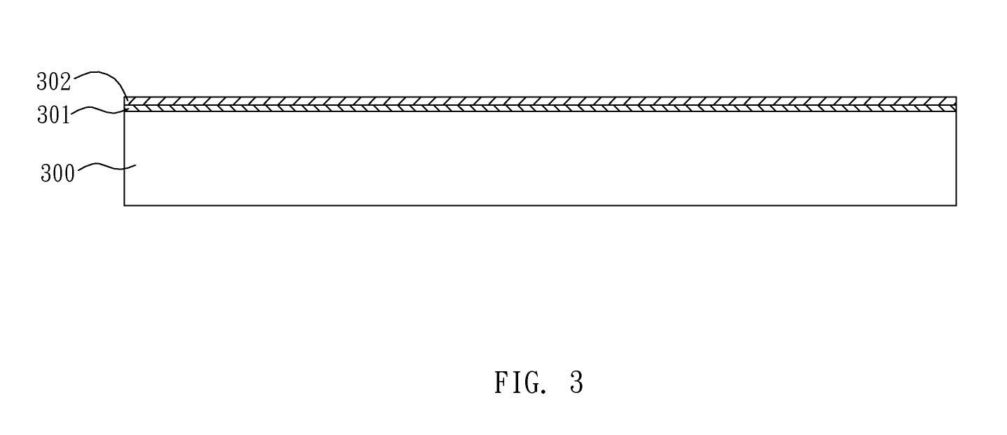

Referring to FIG. 3, it shows the manufacturing process of a microelectromechanical microphone chip with a first insulating layer and a second insulating layer disposing on the base plate according to the present invention. Firstly, a silicon base plate 300 is provided, and a first insulating layer 301 and a second insulating layer 302 are formed on the base plate 300. In this embodiment, the first insulating layer 301 is made of silicon dioxide, and the second insulating layer 302 is made of silicon nitride.

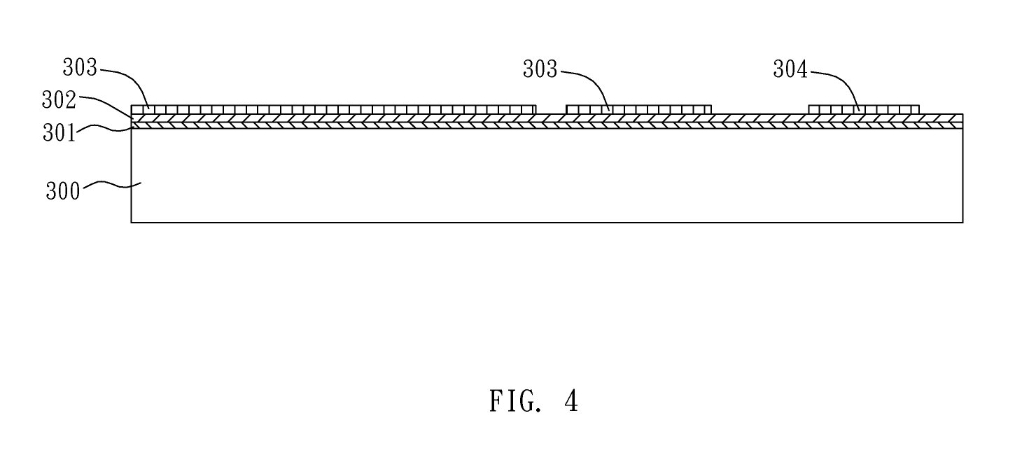

FIG. 4 shows the manufacturing process of a vibration membrane and a first electrode of a microelectromechanical microphone chip according to the present invention. Herein, a vibration membrane 303 and a first electrode 304 are formed by polysilicon to be disposed on the second insulating layer 302.

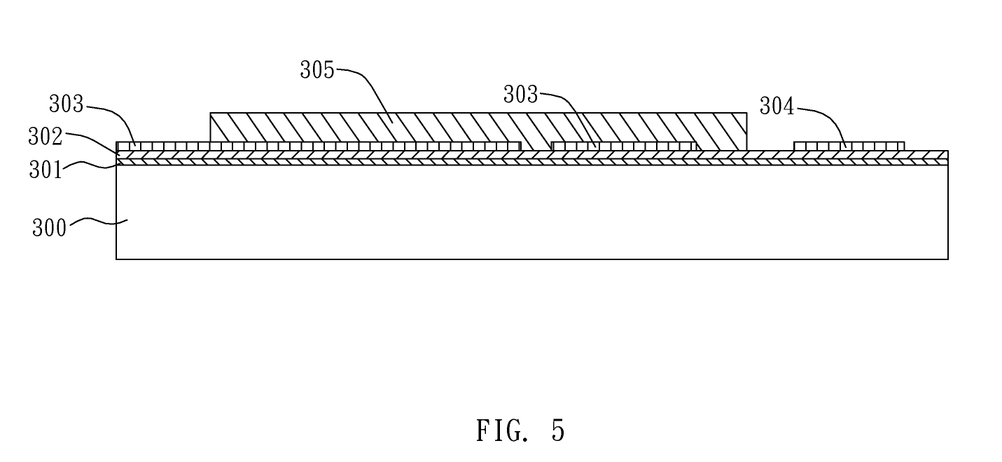

Referring to FIG. 5, it shows the manufacturing process of a sacrificial layer being deposited on a microelectromechanical microphone chip according to the present invention. A sacrificial layer 305 made of silicon dioxide is deposited on the vibration membrane 303.

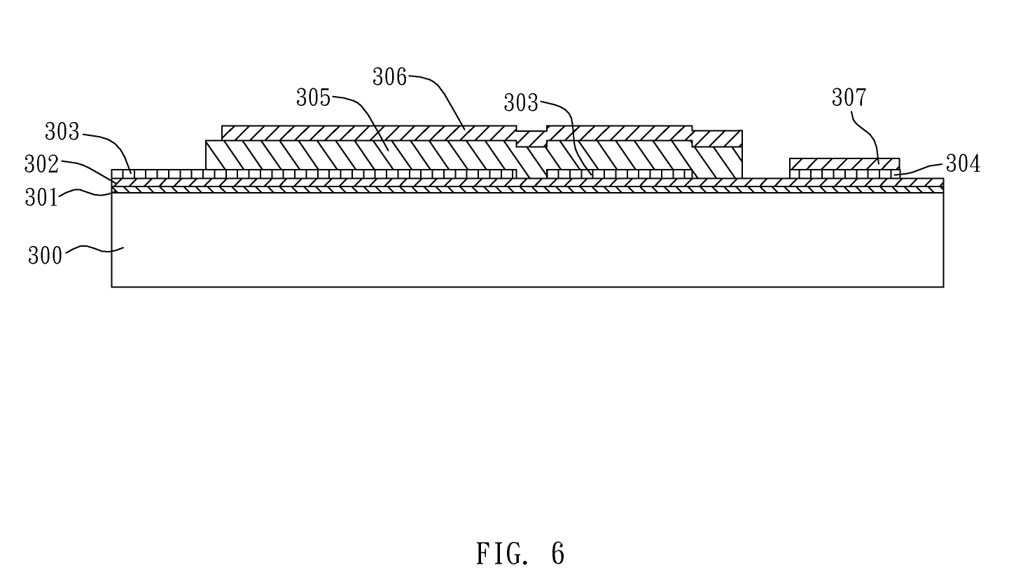

FIG. 6 shows the manufacturing process of a third insulating layer and a capacitor dielectric layer of a microelectromechanical microphone chip according to the present invention. A third insulating layer 306 and a dielectric layer 307 made of silicon nitride are deposited on the sacrificial layer 305 and the first electrode 304 respectively.

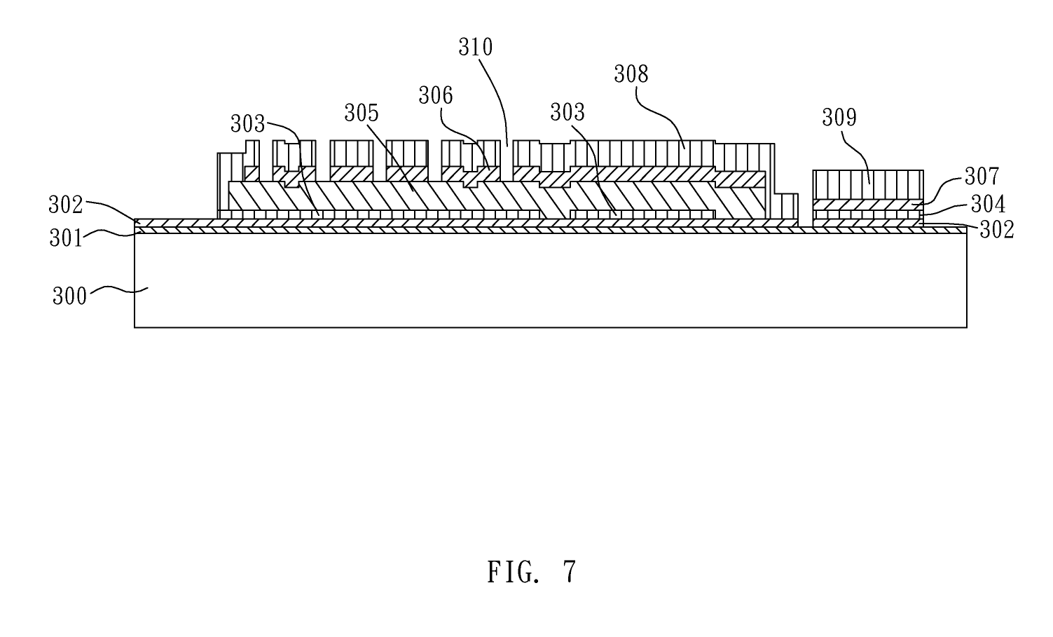

Referring to FIG. 7, it shows the manufacturing process of a back plate and a second electrode of a microelectromechanical microphone chip according to the present invention. A conductive layer 308 and a second electrode 309 made of polysilicon are deposited on the third insulating layer 306 and the dielectric layer 307 respectively. Besides, a plurality of sound holes 310 are etched by method of wet etching on the third insulating layer 306 and the conductive layer 308 at appropriate locations.

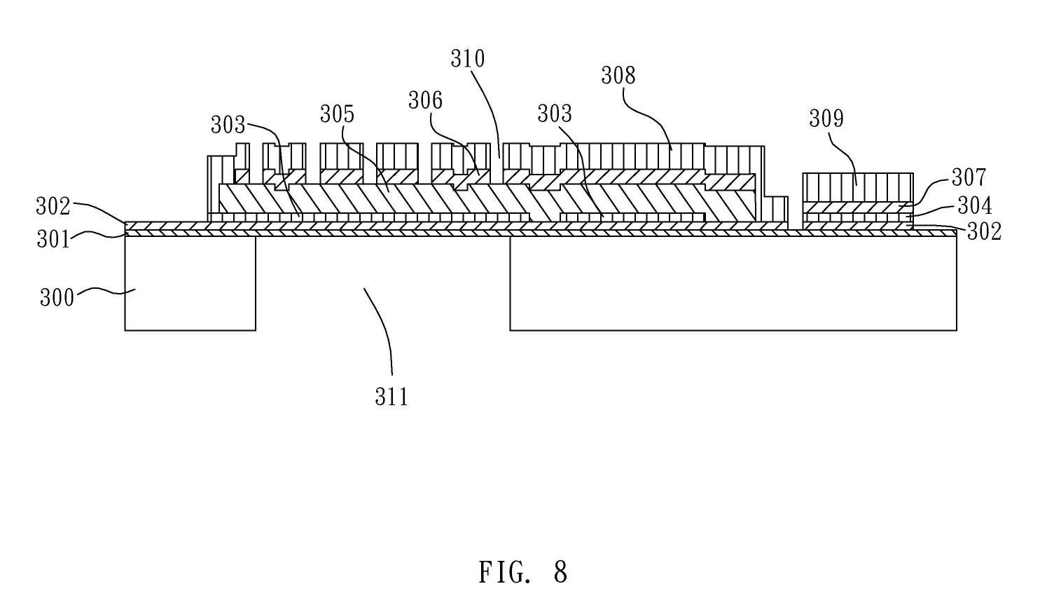

FIG. 8 shows the manufacturing process of etching of a base plate of a microelectromechanical microphone chip according to the present invention. A cavity 311 is formed in the base plate 300 by using inductively coupled plasma reactive ion etching system.

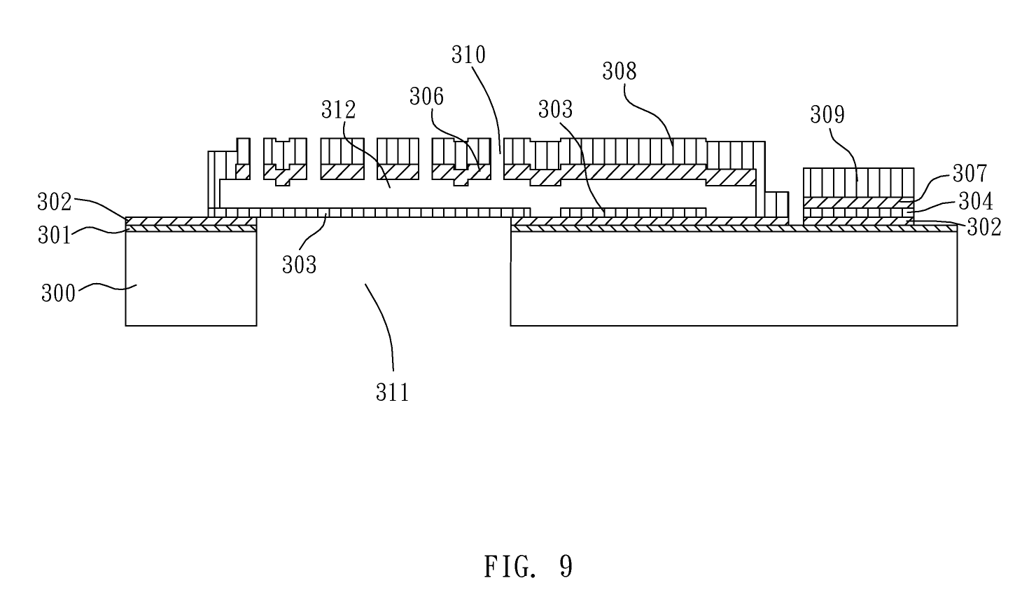

FIG. 9 shows the manufacturing process of removing a sacrificial layer of a microelectromechanical microphone chip according to the present invention. A space 312 is formed by removing the sacrificial layer 305; the first insulating layer 301 as well as the second insulating layer 302 are also removed. Therefore, sound enters into the space 312 through the sound holes 310 in order to vibrate the vibration membrane 303.

Related technology of conventional microelectromechanical microphone chips for converting sound to electrical signals is of prior art. According to the afore-mentioned manufacturing processes, the present invention emphasizes that the filter 31 is formed on the base plate 300. The filter 31 is composed of the second insulating layer 302, the first electrode 304, the dielectric layer 307 and the second electrode 309; all these form a capacitor structure for filter out high frequency noise for microelectromechanical microphones.

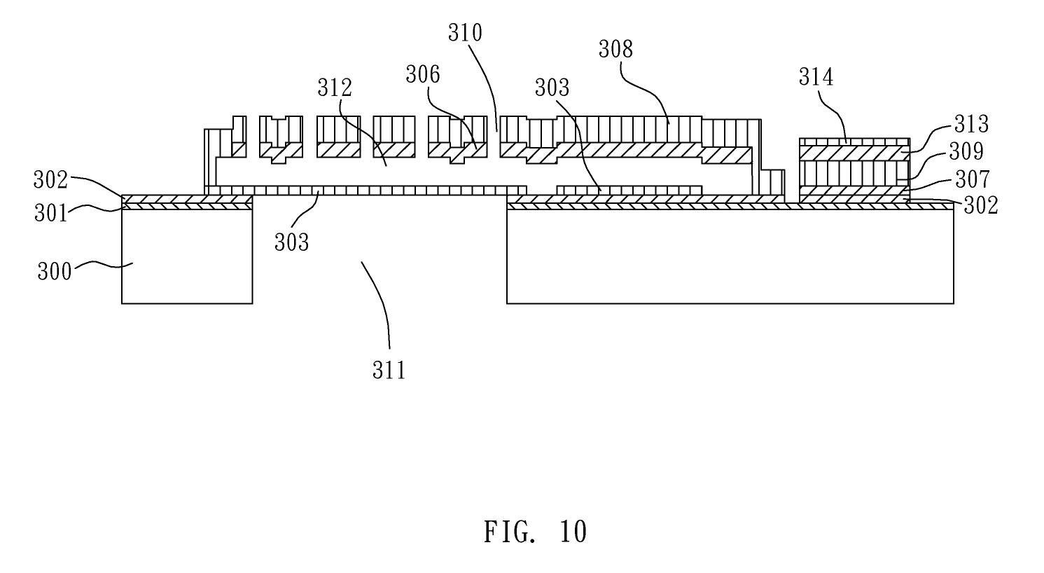

FIG. 10 shows the structure of a microelectromechanical microphone chip formed by another manufacturing process according to the present invention. It is different from the afore-mentioned embodiment in that: the first electrode 304 is not deposited at the time when the vibration membrane 303 is deposited; however, the dielectric layer 307 is deposited on the second insulating layer 302 when the third insulating layer 306 is deposited in this embodiment; the second electrode 309 is deposited on the dielectric layer 307 when the conductive layer 308 is deposited. Then, the structure of the filter 31 is finally formed by deposition of a dielectric layer 313 and a third electrode 314.

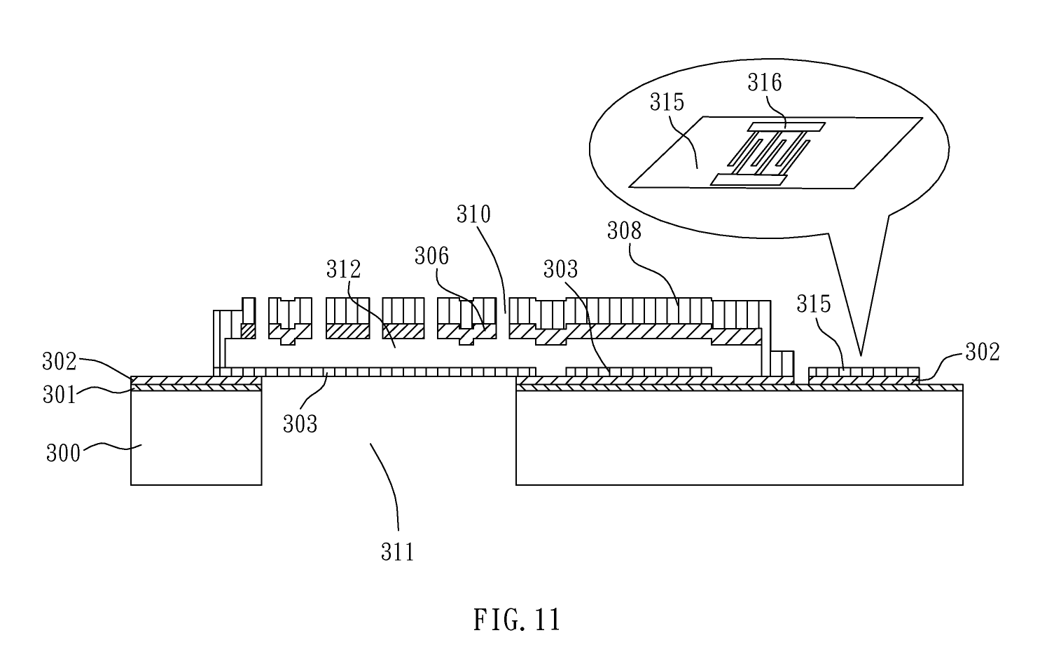

FIG. 11 shows the structure of a microelectromechanical microphone chip formed by yet another manufacturing process according to the present invention. It is different from the afore-mentioned embodiments in that: an electrode layer 315 is deposited directly on the second insulating layer 302; a comb capacitor pattern 316 is formed on the electrode layer 315 by the process of photomask. So that the structure of the filter 31 is formed by the electrode layer 315 and the second insulating layer 302.

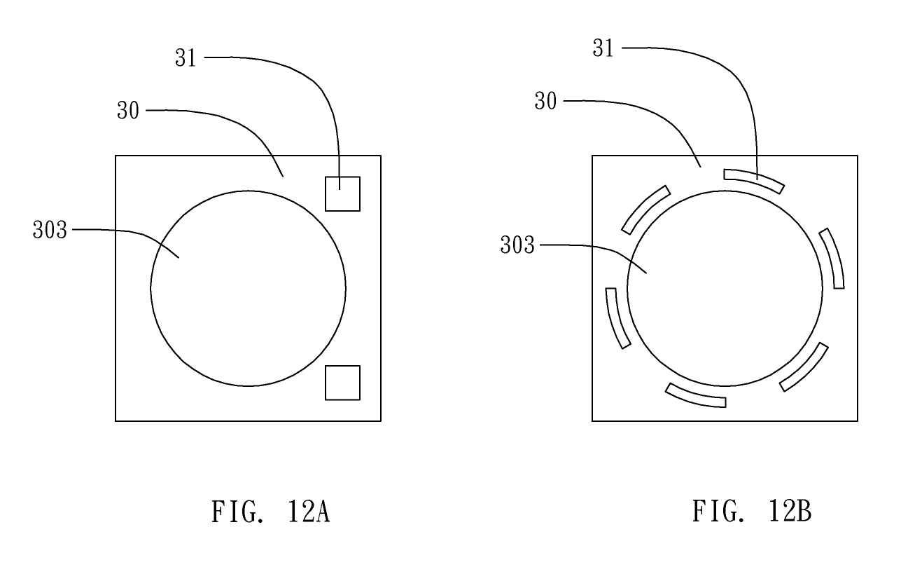

Furthermore, it is necessary to mention as a supplementation. Referring to FIG. 12A, which is a top perspective view of FIG. 2 of the microelectromechanical microphone chip 30 according to the present invention. As shown in the drawing, the filter 31 embedded on the microelectromechanical microphone chip 30 is disposed in two corners by the sides of the vibration membrane 303 respectively. But in another embodiment, it can be arranged as shown in FIG. 12B, a plurality of the filters 31 are disposed around the vibration membrane 303 for improving the support purpose for the vibration membrane 303. Its related manufacturing process can be referred to FIGS. 3 to 11.

At last, it is necessary to mention that, aside from the filter 31 being embodied as a capacitor, it can also be an inductor, a RC filter, a LC filter or a RLC filter. They will not be illustrated by figures or explained here as related manufacturing processes are readily attainable by a person with average skill of microelectromechanical.

As a conclusion, a microelectromechanical microphone chip of a microelectromechanical microphone according to the present invention employs semi-conductor manufacturing technology to integrate a filter on the microelectromechanical microphone chip, to substitute for conventional technology of disposing a capacitor on a base plate. The present invention makes it possible that, without increasing the size of the microelectromechanical microphone chip, the size of the base plate, and even the overall size of the microelectromechanical microphone itself can be reduced. Furthermore, the processes of die bonding and wire bonding are not needed anymore in order to save the cost of packaging process.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. A microelectromechanical microphone comprises:
a shell body having a cavity and an opening, said opening connects said cavity with external environment;
a microelectromechanical microphone chip disposed on an electrical circuit layout inside said cavity, and a filter is integrated with said microelectromechanical microphone chip at an appropriate location; and
an integrated circuit disposed on said electrical circuit layout and is electrically connected to said microelectromechanical microphone chip.

2. The microelectromechanical microphone as claimed in claim 1, wherein said shell body is composed of a base plate and a cover, said opening is disposed on said base plate or said cover at an appropriate location.

3. The microelectromechanical microphone as claimed in claim 2, wherein said microelectromechanical microphone chip and said integrated circuit are disposed on said base plate.

4. The microelectromechanical microphone as claimed in claim 2, wherein said cover is composed of a middle plate and an upper plate which are stacked together.

5. The microelectromechanical microphone as claimed in claim 2, wherein said base plate is a printed circuit board.

6. The microelectromechanical microphone as claimed in claim 1, wherein said filter is a capacitor, an inductor, a RC filter, a LC filter or a RLC filter.

7. A microelectromechanical microphone chip integrated with a filter comprises:
a base plate having a cavity;
a vibration membrane disposed on top of said cavity;
a back plate covering said vibration membrane and maintaining a distance from said vibration membrane, said back plate having a plurality of sound holes; and
a filter disposed on said base plate and is adjacent to said vibration membrane and said back plate.

8. The microelectromechanical microphone chip integrated with a filter as claimed in claim 7, wherein said base plate further including an insulating layer.

9. The microelectromechanical microphone chip integrated with a filter as claimed in claim 7, wherein said filter including two electrodes.

10. The microelectromechanical microphone chip integrated with a filter as claimed in claim 7, wherein said filter including an insulating layer and an electrode layer, said insulating layer is disposed on said base plate, said electrode layer is disposed on said insulating layer, and said electrode layer having a comb capacitor pattern on its top.
